(19) United States
(12) Patent Application Publication
(10) Pub. No.: US 2025/0029942 A1
(43) Pub. Date: Jan. 23, 2025

(54) SEMICONDUCTOR PACKAGE

(71) Applicant: SAMSUNG ELECTRONICS CO., LTD., SUWON-SI (KR)

(72) Inventors: Raeyoung KANG, SUWON-SI (KR); MINKI KIM, SUWON-SI (KR); JIHOON KIM, SUWON-SI (KR); JINKYEONG SEOL, SUWON-SI (KR)

(21) Appl. No.: 18/596,286

(22) Filed: Mar. 5, 2024

(30) Foreign Application Priority Data
Jul. 17, 2023 (KR) 10-2023-0092423

(51) Int. Cl. H01L 23/00; H01L 23/48

(52) U.S. Cl. CPC H01L 24/05; H01L 23/481; H01L 24/08; H01L 2224/02215; H01L 2224/08145

(57) ABSTRACT

A semiconductor package includes a lower structure and an upper structure on the lower structure. The lower structure includes a first substrate, a first through-electrode penetrating the first substrate in a first direction, a first pad connected to the first through-electrode, and a first protective layer surrounding the first pad. The upper structure includes a second substrate, a second through-electrode penetrating the second substrate in the first direction, a second pad connected to the second through-electrode, and a second protective layer surrounding the second pad. The second pad is offset from the first pad in a second direction crossing the first direction. The first pad has a first portion not overlapping the second pad. A first barrier pattern is disposed between the first portion and the second protective layer. A portion of the first barrier pattern is disposed between the first pad and the second pad.

### CROSS-REFERENCE TO RELATED APPLICATIONS

This U.S. non-provisional patent application claims priority under 35 U.S.C. § 119 from Korean Patent Application No. 10-2023-0092423, filed on Jul. 17, 2023 in the Korean Intellectual Property Office, the contents of which are herein incorporated by reference in their entirety.

### TECHNICAL FIELD

Embodiments of the present disclosure are directed to a directly bonded semiconductor package and a method of manufacturing the same.

### DISCUSSION OF THE RELATED ART

As high-capacity, thin and small semiconductor devices and electronic products that use the same have been increasingly demanded in the semiconductor industry, various package techniques relative thereto have been developed. In one of these package techniques, various semiconductor chips are vertically stacked to realize a high dense chip stack structure. According to this technique, semiconductor chips that have various functions can be integrated on a smaller area than a general package that has a single semiconductor chip.

An integrated circuit chip can be realized in the form of a semiconductor package that can be appropriately incorporated into an electronic product. In a typical semiconductor package, a semiconductor chip is mounted on a printed circuit board and electrically connected to the printed circuit board through bonding wires or bumps. Various techniques that increase reliability and durability of semiconductor packages have been studied.

### SUMMARY

Embodiments of the inventive concepts provide a semiconductor package with increased structural stability, and a method of manufacturing the same.

Embodiments of the inventive concepts also provide a method of manufacturing a semiconductor package that can reduce or minimize occurrence of failure, and a semiconductor package manufactured thereby.

Embodiments of the inventive concepts further provide a semiconductor package with increased electrical characteristics and driving stability, and a method of manufacturing the same.

In an embodiment, a semiconductor package includes a lower structure and an upper structure disposed on the lower structure. The lower structure includes a first substrate, a first through-electrode that penetrates the first substrate in a first direction, a first pad connected to the first through-electrode, and a first protective layer that surrounds the first pad. The upper structure includes a second substrate, a second through-electrode that penetrates the second substrate in the first direction, a second pad connected to the second through-electrode, and a second protective layer that surrounds the second pad. The second pad is offset from the first pad in a second direction that crosses the first direction. The first pad includes a first portion that does not overlap the second pad. The semiconductor package further includes a first barrier pattern disposed between the first portion and the second protective layer. A portion of the first barrier pattern is disposed between the first pad and the second pad.

In an embodiment, a semiconductor package includes a lower structure and an upper structure disposed on the lower structure. The lower structure includes a first pad and a first protective layer that surrounds a side surface of the first pad. The upper structure includes a second pad and a second protective layer that surrounds a side surface of the second pad. A top surface of the first pad is partially in contact with a bottom surface of the second pad. The first pad includes a first offset portion adjacent to the second protective layer, and a first overlapping portion that overlaps the second pad. The second pad includes a second offset portion adjacent to the first protective layer, and a second overlapping portion that overlaps the first pad. A first barrier pattern is disposed between the first offset portion and the second protective layer and between the first overlapping portion and the second pad. A second barrier pattern is disposed between the second offset portion and the first protective layer and between the second overlapping portion and the first pad.

In an embodiment, a semiconductor package includes a lower structure and an upper structure disposed on the lower structure. The lower structure includes a first substrate that includes a first device region, a first through-electrode that penetrates the first substrate in a first direction, a first pad connected to the first through-electrode, and a first protective layer that surrounds the first pad. The upper structure includes a second substrate that includes the first device region, a second through-electrode that penetrates the second substrate in the first direction, a second pad connected to the second through-electrode, and a second protective layer that surrounds the second pad. The second pad is offset from the first pad in a second direction that crosses the first direction and is in contact with the first pad. The semiconductor package further includes a first barrier pattern disposed between the first pad and the second pad. The first barrier pattern includes a first barrier portion located on an edge of a top surface of the first pad, a second barrier portion located on an edge of a bottom surface of the second pad, where the first barrier portion and the second barrier portion partially overlap each other, a first single portion disposed between the first pad and the second protective layer, and an overlap portion disposed between the first pad and the second pad and where the first barrier portion overlaps the second barrier portion. A thickness of the first single portion is less than a thickness of the overlap portion.

### BRIEF DESCRIPTION OF THE DRAWINGS

FIG. 1 is a cross-sectional view of a semiconductor package according to some embodiments of the inventive concepts.

FIG. 2A is an enlarged cross-sectional view of a region ‘M’ of FIG. 1.

FIG. 2B is an enlarged cross-sectional view of a region ‘O’ of FIG. 2A.

FIGS. 2C and 2D are enlarged cross-sectional views that correspond to the region ‘M’ of FIG. 1 of a semiconductor package according to some embodiments of the inventive concepts.

FIG. 3 is a plan view taken along a line X-X′ of FIG. 1.

FIGS. 4A to 4C are plan views of a region ‘N’ of FIG. 3 of a semiconductor package according to some embodiments of the inventive concepts.

FIG. 5 is a cross-sectional view of a semiconductor package according to some embodiments of the inventive concepts.

FIGS. 6A to 8 are cross-sectional views that illustrate a method of manufacturing a semiconductor package according to some embodiments of the inventive concepts.

### DETAILED DESCRIPTION

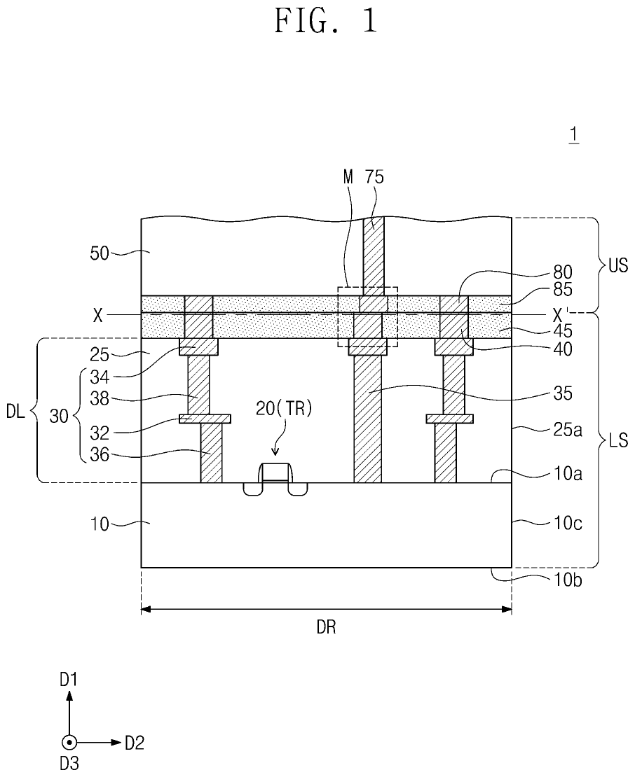

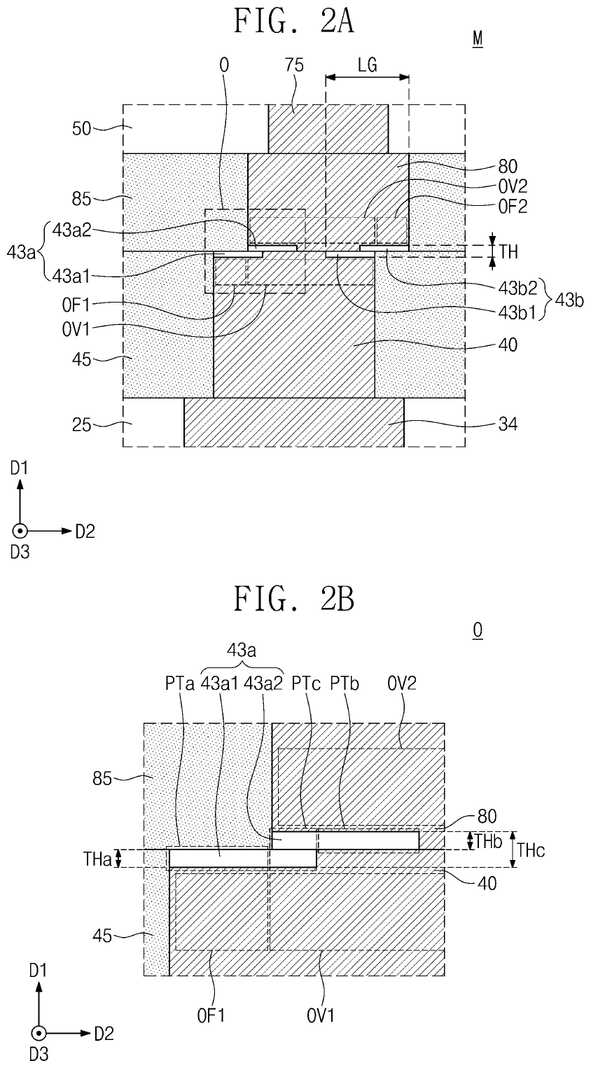

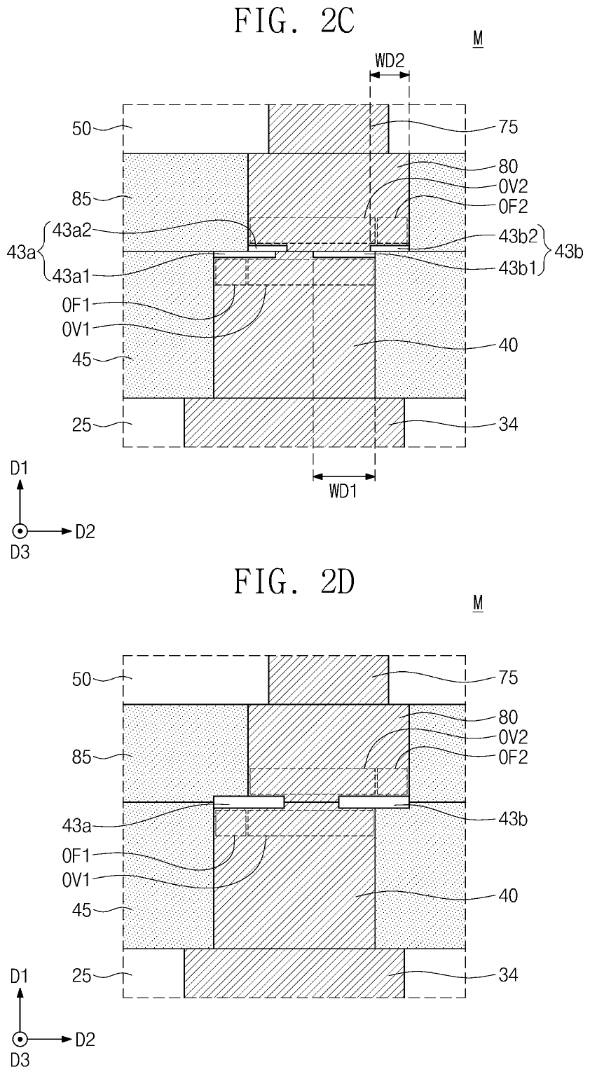

Embodiments of the inventive concepts will be described hereinafter with reference to the accompanying drawings. FIG. 1 is a cross-sectional view of a semiconductor package according to some embodiments of the inventive concepts. FIG. 2A is an enlarged cross-sectional view of a region ‘M’ of FIG. 1. FIG. 2B is an enlarged cross-sectional view of a region ‘O’ of FIG. 2A.

Referring to FIGS. 1, 2A and 2B, in an embodiment, a semiconductor package 1 includes a lower structure LS and an upper structure US.

The lower structure LS includes a first semiconductor substrate 10 and a circuit structure disposed on the first semiconductor substrate 10. For example, the lower structure LS corresponds to a semiconductor die. The first semiconductor substrate 10 includes a semiconductor material. For example, the first semiconductor substrate 10 is a single-crystalline silicon substrate.

The first semiconductor substrate 10 includes a device region DR. The device region DR is located at a central portion of the first semiconductor substrate 10 when viewed in a plan view.

The first semiconductor substrate 10 includes a first surface 10a and a second surface 10b that are opposite to each other. The first surface 10a of the first semiconductor substrate 10 may be a front surface of the first semiconductor substrate 10, and the second surface 10b may be a back surface of the first semiconductor substrate 10. The front surface 10a of the first semiconductor substrate 10 is a surface of the first semiconductor substrate 10 on which semiconductor devices, interconnection lines and/or pads are formed. The back surface 10b of the first semiconductor substrate 10 is another surface of the first semiconductor substrate 10 that is opposite to the front surface.

The circuit structure is disposed on the first semiconductor substrate 10. The circuit structure includes a device layer DL and a first protective layer 45 that are sequentially stacked on the first surface 10a of the first semiconductor substrate 10.

The device layer DL includes a semiconductor device 20 and a device interconnection portion 30. The semiconductor device 20 includes transistors TR disposed on the first surface 10a of the device region DR of the first semiconductor substrate 10. For example, each of the transistors TR includes a source and a drain that are formed in an upper portion of the first semiconductor substrate 10, a gate electrode disposed on the first surface 10a of the first semiconductor substrate 10, and a gate insulating layer disposed between the first semiconductor substrate 10 and the gate electrode. For convenience of illustration, a single transistor TR is illustrated in FIG. 1, but embodiments of the inventive concepts are not necessarily limited thereto. The semiconductor device 20 includes a plurality of the transistors TR. For example, the semiconductor device 20 may include a shallow device isolation pattern and a logic cell, or a plurality of memory cells, on the first surface 10a of the device region DR. For example, the semiconductor device 20 may include a passive device such as a capacitor.

The first surface 10a of the first semiconductor substrate 10 is covered with a device interlayer insulating layer 25. The device interlayer insulating layer 25 covers the semiconductor device 20 in the device region DR. The device interlayer insulating layer 25 covers the semiconductor device 20 from above. For example, the semiconductor device 20 is not exposed by the device interlayer insulating layer 25. A side surface 25a of the device interlayer insulating layer 25 is aligned with a side surface 10c of the first semiconductor substrate 10. For example, the side surface 25a of the device interlayer insulating layer 25 is coplanar with the side surface 10c of the first semiconductor substrate 10.

In some embodiments, the device interlayer insulating layer 25 includes at least one of silicon oxide (SiO), silicon nitride (SiN), or silicon oxynitride (SiON). In other embodiments, the device interlayer insulating layer 25 includes a low-k dielectric material. The device interlayer insulating layer 25 may have a mono-layered or a multi-layered structure. When the device interlayer insulating layer 25 has a multi-layered structure, interconnection layers to be described below are disposed in insulating layers, and an etch stop layer is disposed between the insulating layers. For example, the etch stop layer is disposed on a bottom surface of the insulating layer. For example, the etch stop layer includes at least one of silicon nitride (SiN), silicon oxynitride (SiON), or silicon carbonitride (SiCN).

The device interconnection portion 30 connected to the transistors TR is disposed in the device interlayer insulating layer 25 in the device region DR.

The device interconnection portion 30 includes first signal line patterns 32 and second signal line patterns 34 located above the first signal line patterns 32 and that are buried in the device interlayer insulating layer 25. The first signal line patterns 32 and the second signal line patterns 34 are for horizontal interconnection. The first signal line patterns 32 are located between a top surface and a bottom surface of the device interlayer insulating layer 25. The second signal line patterns 34 are disposed in an upper portion of the device interlayer insulating layer 25. For example, top surfaces of the second signal line patterns 34 are exposed at the top surface of the device interlayer insulating layer 25. For example, the second signal line patterns 34 are uppermost line patterns of the device interconnection portion 30 that are disposed in the device interlayer insulating layer 25.

A thickness of each of the second signal line patterns 34 is greater than a thickness of each of the first signal line patterns 32. For example, the thickness of each of the second signal line patterns 34 ranges from 1 μm to 10 μm. The first signal line patterns 32 and the second signal line patterns 34 are not located on an edge region of the first semiconductor substrate 10. The first signal line patterns 32 and the second signal line patterns 34 include at least one of copper (Cu) or tungsten (W).

The device interconnection portion 30 further includes first connection contacts 36 that connect the first signal line patterns 32 to the semiconductor device 20 or the first semiconductor substrate 10, and second connection contacts 38 that connect the first signal line patterns 32 to the second signal line patterns 34. The first connection contacts 36 and the second connection contacts 38 are for vertical interconnection. At least one of the first connection contacts 36 vertically penetrates a portion of the device interlayer insulating layer 25 to be connected to one of the source electrode, the drain electrode or the gate electrode of the transistor TR. In addition, at least one of the first connection contacts 36 is connected to at least one of the various other components of the semiconductor device 20.

The first connection contacts 36 penetrate a portion of the device interlayer insulating layer 25 in a first direction D1 to be connected to bottom surfaces of the first signal line patterns 32. The second connection contacts 38 penetrate a portion of the device interlayer insulating layer 25 in the first direction D1 to be connected to top surfaces of the first signal line patterns 32 and bottom surfaces of the second signal line patterns 34. The first connection contacts 36 and the second connection contacts 38 include tungsten (W).

A single interconnection layer, such as the first signal line patterns 32, is disposed between the first semiconductor substrate 10 and the second signal line patterns 34 in FIG. 1, but embodiments of the inventive concepts are not necessarily limited thereto. In some embodiments, a plurality of the interconnection layers are disposed between the first semiconductor substrate 10 and the second signal line patterns 34. For example, in some embodiments, other line patterns are provided between the first signal line patterns 32 and the second signal line patterns 34 or between the first semiconductor substrate 10 and the first signal line patterns 32. For example, the other line patterns, the first signal line patterns 32 and the second signal line patterns 34 are electrically connected to each other through connection contacts. Hereinafter, the embodiments of FIG. 1 will be described.

The device interconnection portion 30 further includes a through-electrode 35 that connects the first semiconductor substrate 10 to a corresponding second signal line pattern 34. The through-electrode 35 is for vertical interconnection. The through-electrode 35 penetrates the device interlayer insulating layer 25 in the first direction D1 to be connected to one of the source electrode, the drain electrode or the gate electrode of the transistor TR. However, in some embodiments, the through-electrode 35 is connected to at least one of the various other components of the semiconductor device 20. The through-electrode 35 penetrates the device interlayer insulating layer 25 in the first direction D1 to be connected to the bottom surface of a corresponding second signal line patterns 34. The through-electrode 35 includes tungsten (W). In some embodiments, the through-electrode 35 is exposed at a bottom surface of the first semiconductor substrate 10.

In some embodiments, a seed layer or a barrier layer is provided on a side surface and a bottom surface of each of the first connection contacts 36, the second connection contacts 38 and the through-electrode 35. The seed layer or the barrier layer is disposed between the device interlayer insulating layer 25 and each of the first connection contacts 36, the second connection contacts 38 and the through-electrode 35. The seed layer includes gold (Au), and the barrier layer includes at least one of titanium (Ti), titanium nitride (TiN), tantalum (Ta), tantalum nitride (TaN), or tungsten nitride (WN).

The semiconductor device 20, the transistors TR of the semiconductor device 20, the device interlayer insulating layer 25 and the device interconnection portion 30 constitute the device layer DL.

First pads 40 are disposed on the device interlayer insulating layer 25. The first pads 40 are disposed on the top surfaces of the second signal line patterns 34. The first pads 40 are in direct contact with the top surfaces of the second signal line patterns 34. A width in a second direction D2 that crosses the first direction D1 of each of the first pads 40 is substantially uniform as a distance from the first semiconductor substrate 10 increases. However, in some embodiments, unlike FIG. 1, the width of each of the first pads 40 progressively decreases toward the first semiconductor substrate 10. A thickness of each of the first pads 40 is substantially uniform. For example, each of the first pads 40 has a flat shape. In some embodiments, each of the first pads 40 includes a via portion and a pad portion on the via portion that are connected to each other in a single integrated body, and have a T-shaped cross section formed by the via portion and the pad portion.

A planar shape of each of the first pads 40 is one of a tetragonal shape or a circular shape. In addition, the planar shape of each of the first pads 40 is one of a circular shape, an elliptical shape, a tetragonal shape, a hexagonal shape, or a polygonal shape. However, embodiments of the inventive concepts are not necessarily limited thereto, and in some embodiments, the planar shape of each of the first pads 40 can be variously changed as needed. The first pads 40 include a metal. For example, the first pads 40 include copper (Cu).

The first pads 40 are electrically connected to the semiconductor device 20. For example, as shown in FIG. 1, the first pads 40 are connected to the top surfaces of the second signal line patterns 34 of the device interconnection portion 30 on the device region DR. For example, the second signal line patterns 34 are under pad patterns disposed in the device interlayer insulating layer 25. The device interconnection portion 30 vertically extends in the device interlayer insulating layer 25 to be connected to the first pads 40. The second signal line patterns 34 electrically connect the semiconductor device 20 to the first pads 40.

The first protective layer 45 is disposed on the device interlayer insulating layer 25. The first protective layer 45 covers the second signal line patterns 34 on the top surface of the device interlayer insulating layer 25. The first protective layer 45 surrounds the first pads 40 on the top surface of the device interlayer insulating layer 25. The first pads 40 are exposed by the first protective layer 45. For example, the first protective layer 45 surround the first pads 40 but do not cover the first pads 40, when viewed in a plan view. A top surface of the first protective layer 45 is coplanar with top surfaces of the first pads 40. The first protective layer 45 includes at least one of a high density plasma (HDP) oxide, an undoped silicate glass (USG), tetraethyl orthosilicate (TEOS), silicon nitride (SiN), silicon oxide (SiO), silicon oxy-carbide (SiOC), silicon oxynitride (SiON), or silicon carbonitride (SiCN). The first protective layer 45 may have a mono-layered or multi-layered structure.

Each of the first pads 40 has a damascene structure in the first protective layer 45. For example, each of the first pads 40 further includes a seed/protection pattern that covers a side surface and a bottom surface of each of the first pads 40. The seed/protection patterns conformally cover the side surfaces and the bottom surfaces of the first pads 40. The seed/protection patterns are disposed between the first protective layer 45 and the first pads 40 and between the first pads 40 and the second signal line patterns 34. When the seed/protection pattern is used as a seed pattern, the seed/protection pattern includes a metal such as gold (Au). When the seed/protection pattern is used as a protection pattern, the seed/protection patterns include a metal such as titanium (Ti) or tantalum (Ta), and/or a metal nitride, such as one of titanium nitride (TiN) or tantalum nitride (TaN)).

The upper structure US is disposed on the lower structure LS. The upper structure US includes a second semiconductor substrate 50, a second protective layer 85, and second pads 80. The upper structure US corresponds to a semiconductor die.

The second semiconductor substrate 50 may be a semiconductor wafer. In some embodiments, the second semiconductor substrate 50 includes one of a bulk silicon substrate, a silicon-on-insulator (SOI) substrate, a germanium (Ge) substrate, a germanium-on-insulator (GOI) substrate, a silicon-germanium (SiGe) substrate, or a substrate that includes an epitaxial thin layer obtained by performing a selective epitaxial growth (SEG) process. For example, the second semiconductor substrate 50 includes at least one of silicon (Si), germanium (Ge), silicon-germanium (SiGe), gallium arsenic (GaAs), indium gallium arsenic (InGaAs), aluminum gallium arsenic (AlGaAs), or any mixture thereof. In some embodiments, the second semiconductor substrate 50 is an insulating substrate such as a printed circuit board (PCB).

In some embodiments, a semiconductor device such as a transistor is disposed on the second semiconductor substrate 50. For example, the semiconductor device is covered with a device interlayer isolation layer on the second semiconductor substrate 50.

The second pads 80 are disposed on the second semiconductor substrate 50. The second pads 80 are disposed on a bottom surface of the second semiconductor substrate 50, which faces the lower structure LS. A width in the second direction D2 of each of the second pads 80 progressively decreases toward the second semiconductor substrate 50. However, in some embodiments, as shown in FIG. 1, the width of each of the second pads 80 is substantially uniform as a distance from the second semiconductor substrate 50 increases. A thickness of each of the second pads 80 is substantially uniform. For example, each of the second pads 80 has a flat shape.

In some embodiments, each of the second pads 80 includes a via portion and a pad portion on the via portion that are connected to each other in a single integrated body, and have a T-shaped cross section formed by the via portion and the pad portion. A planar shape of each of the second pads 80 is one of a circular shape, an elliptical shape, a tetragonal shape, a hexagonal shape, or a polygonal shape. A material of the second pads 80 is the same as the material of the first pads 40. The second pads 80 include a metal. For example, the second pads 80 include copper (Cu).

The second protective layer 85 is disposed on the second semiconductor substrate 50. The second protective layer 85 surrounds the second pads 80 on the bottom surface of the second semiconductor substrate 50. Bottom surfaces of the second pads 80 are exposed by the second protective layer 85. For example, the second protective layer 85 surrounds the second pads 80 but does not cover the second pads 80, when viewed in a plan view. A bottom surface of the second protective layer 85 is coplanar with the bottom surfaces of the second pads 80. The second protective layer 85 includes an oxide, a nitride or an oxynitride of the material of the second semiconductor substrate 50. The second protective layer 85 includes an insulating material such as at least one of silicon oxide (SiO), silicon nitride (SiN), silicon oxynitride (SiON), or silicon carbonitride (SiCN). For example, the second protective layer 85 includes silicon oxide (SiO).

The upper structure US is disposed on the lower structure LS. The first pads 40 of the lower structure LS are vertically aligned with the second pads 80 of the upper structure US. The lower structure LS is in direct contact with the upper structure US.

The first protective layer 45 of the lower structure LS and the second protective layer 85 of the upper structure US are bonded to each other at an interface between the lower structure LS and the upper structure US. For example, the first protective layer 45 and the second protective layer 85 are bonded to each other by a hybrid bonding of an oxide, nitride or oxynitride. In the present specification, hybrid bonding means that two components that include the same type of materials are fused together at their interface. For example, the first protective layer 45 and the second protective layer 85 that are bonded to each other constitute a continuous component, and an interface between the first protective layer 45 and the second protective layer 85 is not visible. For example, the first protective layer 45 and the second protective layer 85 are formed of the same material, and an interface might not exist between the first protective layer 45 and the second protective layer 85. For example, the first protective layer 45 and the second protective layer 85 are provided as a single integrated component. For example, the first protective layer 45 and the second protective layer 85 are bonded to each other to constitute a single body. However, embodiments of the inventive concepts are not necessarily limited thereto.

In some embodiments, the first protective layer 45 and the second protective layer 85 are formed of different materials. The first protective layer 45 and the second protective layer 85 do not constitute a continuous component, and an interface between the first protective layer 45 and the second protective layer 85 may be visible. The first protective layer 45 and the second protective layer 85 are bonded to each other, but each of the first protective layer 45 and the second protective layer 85 is provided as an individual component.

The upper structure US is connected to the lower structure LS. For example, the upper structure US is in direct contact with the lower structure LS. The first pads 40 of the lower structure LS are bonded to the second pads 80 of the upper structure US at the interface between the upper structure US and the lower structure LS. For example, the first pads 40 are bonded to the second pads 80 by metal-metal hybrid bonding. For example, the bonded first pad 40 and second pad 80 constitute a continuous component. An interface between the first pad 40 and the second pad 80 is not visible. For example, the first pad 40 and the second pad 80 include a same material, and no interface exists between the first pad 40 and the second pad 80. For example, the first pad 40 and the second pad 80 are connected to each other in a single integrated body and thus are provided as a single component.

Referring to FIG. 2A, in an embodiment, the second pad 80 is offset from the first pad 40 in the second direction D2. The first pad 40 includes a first offset portion OF1 that does not overlap the second pad 80, and a first overlapping portion OV1 that overlaps the second pad 80. The second pad 80 includes a second offset portion OF2 that does not overlap the first pad 40, and a second overlapping portion OV2 that overlaps with the first pad 40. The first and second offset portions OF1 and OF2 are formed because the first pad 40 and the second pad 80 might be misaligned with each other when they are bonded to each other in a manufacturing method to be described below.

A first barrier pattern 43a is disposed between the first offset portion OF1 and the second protective layer 85 and between the first overlapping portion OV1 and the second overlapping portion OV2. A second barrier pattern 43b is disposed between the second offset portion OF2 and the first protective layer 45 and between the first overlapping portion OV1 and the second overlapping portion OV2. The first and second barrier patterns 43a and 43b are also be disposed between the first protective layer 45 and the second protective layer 85.

The first barrier pattern 43a and the second barrier pattern 43b are respectively provided at both sides of a portion in which the first pad 40 and the second pad 80 are in direct contact with each other. A thickness TH of each of the first and second barrier patterns 43a and 43b ranges from about 1 Å to about 100 Å. A width LG in the second direction of each of the first and second barrier patterns 43a and 43b ranges from about 0.1 μm to about 8 μm.

The first barrier pattern 43a will be described in more detail with reference to FIG. 2B.

Referring to FIG. 2B, in an embodiment, the first barrier pattern 43a includes a first barrier portion 43al disposed on the first pad 40, and a second barrier portion 43a2 disposed under the second pad 80. The first barrier portion 43al and the second barrier portion 43a2 are in contact with each other to form the first barrier pattern 43a. The first barrier portion 43al and the second barrier portion 43a2 may partially or completely overlap with each other. Thus, the first barrier pattern 43a includes an overlap portion PTc in which the first barrier portion 43al overlaps with the second barrier portion 43a2.

The first barrier portion 43al includes a first single portion PTa that does not overlap the second barrier portion 43a2. The first single portion PTa is disposed between the first offset portion OF1 of the first pad 40 and the second protective layer 85. The second barrier portion 43a2 includes a second single portion PTb that does not overlap the first barrier portion 43al. The second single portion PTb is disposed between the first pad 40 and the second pad 80.

A thickness THa of the first single portion PTa and a thickness THb of the second single portion PTb is less than a thickness THc of the overlap portion PTc. The thickness THc of the overlap portion PTc is equal to or less than a sum of the thickness THa of the first single portion PTa and the thickness THb of the second single portion PTb. In some embodiments, unlike FIG. 2B, each of the first single portion PTa and the second single portion PTb has a thickness that progressively increases toward the overlap portion PTc.

Referring again to FIG. 2A, in an embodiment, the second barrier pattern 43b includes the same technical features as the first barrier pattern 43a. The second barrier pattern 43b includes a third barrier portion 43b1 disposed on the first pad 40, and a fourth barrier portion 43b2 disposed under the second pad 80. The first and third barrier portions 43al and 43b1 are disposed on respective edges of an upper portion of the first pad 40. The second and fourth barrier portions 43a2 and 43b2 are disposed under respective edges of a lower portion of the second pad 80.

Each of the first and second barrier patterns 43a and 43b includes a metal. For example, each of the first and second barrier patterns 43a and 43b includes at least one of Ti, Ta, or TiN.

FIGS. 2C and 2D are enlarged cross-sectional views that correspond to the region ‘M’ of FIG. 1 and illustrate semiconductor packages according to some embodiments of the inventive concepts.

Referring to FIG. 2C, in an embodiment, a width in the second direction D2 of the first barrier portion 43al differs from a width in the second direction of the second barrier portion 43a2. A width WD1 in the second direction of the third barrier portion 43b1 differs from a width WD2 in the second direction of the fourth barrier portion 43b2. A width of an overlapping portion of the first barrier portion 43al and the second barrier portion 43a2 differs from a width of an overlapping portion of the third barrier portion 43b1 and the fourth barrier portion 43b2. For example, a width of the first barrier pattern 43a differs from a width of the second barrier pattern 43b. The width of the first barrier portion 43al differs from the width of the third barrier portion 43b1. The width of the second barrier portion 43a2 differs from the width of the fourth barrier portion 43b2.

Referring to FIG. 2D, in an embodiment, each of the first barrier pattern 43a and the second barrier pattern 43b is a mono-layer. This is because a barrier pattern is formed at one of an upper portion of the first pad 40 or a lower portion of the second pad 80 in a manufacturing method to be described below. A thickness of each of the first and second barrier patterns 43a and 43b is uniform.

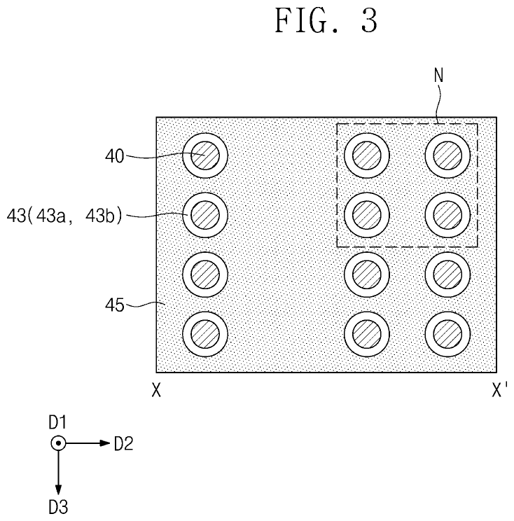

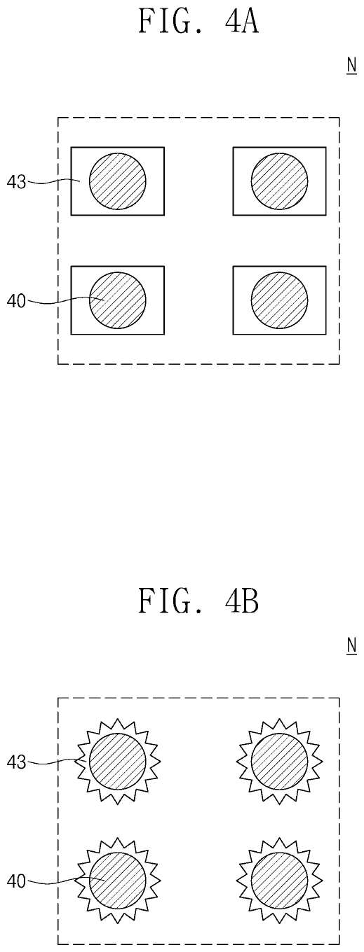

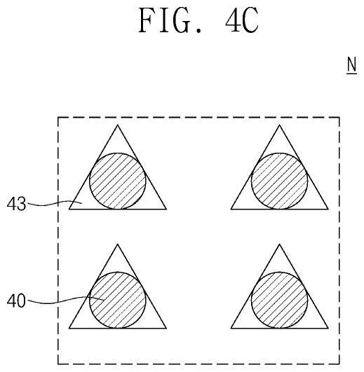

FIG. 3 is a plan view taken along a line X-X′ of FIG. 1. FIGS. 4A to 4C are plan views that correspond to a region ‘N’ of FIG. 3 and that illustrate semiconductor packages according to some embodiments of the inventive concepts.

Referring to FIG. 3, in an embodiment, the first barrier pattern 43a and the second barrier pattern 43b are connected to each other and disposed along an edge of the first pad 40. The first and second barrier patterns 43a and 43b surround the first pad 40. The first pad 40 is spaced apart from the first protective layer 45 by the first and second barrier patterns 43a and 43b.

Referring to FIGS. 4A to 4C, in an embodiment, a planar shape of the first and second barrier patterns 43a and 43b is one of a circular shape, a cogwheel shape, a tetragonal shape, a triangular shape, or a polygonal shape. The planar shape of the first and second barrier patterns 43a and 43b can variously change as needed.

Referring again to FIGS. 1 and 2A to 2D, in an embodiment, the first pad 40 and the second pad 80 can be offset from each other and are bonded to each other, and thus the first pad 40 can be in contact with the second protective layer 85 and/or the second pad 80 can be in contact with the first protective layer 45. According to embodiments of the inventive concepts, the barrier pattern is disposed between the first pad 40 and the second protective layer 85 and between the second pad 80 and the first protective layer 45 to prevent copper ions (Cu²⁺) from diffusing from the first and second pads 40 and 80 into the first and second protective layers 45 and 85. Thus, a short phenomenon of the semiconductor package can be prevented to prevent contact failure between the pads from affecting electrical characteristics of the semiconductor package.

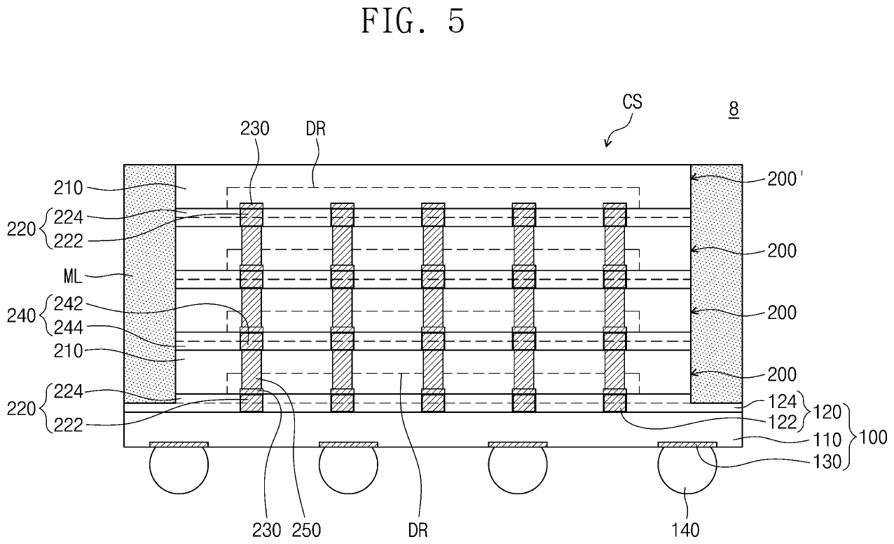

FIG. 5 is a cross-sectional view of a semiconductor package 8 according to some embodiments of the inventive concepts.

Referring to FIG. 5, in some embodiments, a substrate 100 is a package substrate, such as a printed circuit board (PCB), or an interposer substrate provided in a package. In some embodiments, the substrate 100 is a semiconductor substrate on which semiconductor devices are formed or integrated. The substrate 100 includes a substrate base layer 110, a substrate interconnection layer 120 formed on the substrate base layer 110, and second substrate pads 130.

The substrate interconnection layer 120 includes first substrate pads 122 that are exposed on a top surface of the substrate base layer 110, and a substrate protective layer 124 that covers the substrate base layer 110 and surrounds the first substrate pads 122. In some embodiments, top surfaces of the first substrate pads 122 are coplanar with a top surface of the substrate protective layer 124.

The second substrate pads 130 are exposed at a bottom surface of the substrate base layer 110. The substrate 100 redistributes a chip stack CS to be described below. For example, the first substrate pads 122 and the second substrate pads 130 are electrically connected to each other through circuit interconnection lines in the substrate base layer 110 and constitute a redistribution circuit along with the circuit interconnection lines. The first substrate pads 122 and the second substrate pads 130 include a conductive material such as a metal. For example, the first substrate pads 122 and the second substrate pads 130 include copper (Cu). The substrate protective layer 124 includes an insulating material such as at least one of an oxide, a nitride, or an oxynitride of a material of the substrate base layer 110. For example, the substrate protective layer 124 includes silicon oxide (SiO).

Substrate connection terminals 140 are disposed on a bottom surface of the substrate 100. The substrate connection terminals 140 are formed on the second substrate pads 130 of the substrate 100. The substrate connection terminals 140 include solder balls or solder bumps. The semiconductor package 8 has the form of one of a ball grid array (BGA), a fine ball grid array (FBGA) or a land grid array (LGA), depending on a type and arrangement of the substrate connection terminals 140.

A chip stack CS is disposed on the substrate 100. The chip stack CS includes one or more semiconductor chips 200 and 200′ stacked on the substrate 100. Each of the semiconductor chips 200 and 200′ is one of a memory chip such as a DRAM chip, a SRAM chip, a MRAM chip, or a FLASH memory chip. In some embodiments, each of the semiconductor chips 200 and 200 is a logic chip. A single chip stack CS is shown in FIG. 5, but embodiments of the inventive concepts are not necessarily limited thereto. In some embodiments, a plurality of chip stacks are provided, and the chip stacks are spaced apart from each other on the substrate 100.

A semiconductor chip 200 is mounted on the substrate 100. The semiconductor chip 200 includes a semiconductor material such as silicon (Si). The semiconductor chip 200 includes a chip base layer 210, a first chip interconnection layer 220 disposed on a surface of the chip base layer 210 that is adjacent to a front surface of the semiconductor chip 200, and a second chip interconnection layer 240 disposed on another surface of the chip base layer 210 that is adjacent to a back surface of the semiconductor chip 200. In the present specification, the front surface may be defined as a surface adjacent to an active surface of an integrated device in a semiconductor chip, and the back surface may be defined as a surface opposite to the front surface.

The first chip interconnection layer 220 includes first chip pads 222 disposed on the chip base layer 210, and a first chip protective layer 224 that surrounds the first chip pads 222 on the chip base layer 210. The first chip pads 222 correspond to the first pads 40 described with reference to FIGS. 1, 2A and 2B. For example, the chip base layer 210 has a device region DR on which transistors are formed, and includes signal line patterns 230 connected to the transistors in the device region DR and exposed at a bottom surface of the chip base layer 210. The first chip pads 222 are connected to the signal line patterns 230 in the device region DR.

The second chip interconnection layer 240 includes second chip pads 242 disposed on the chip base layer 210, and a second chip protective layer 244 that surround the second chip pads 242 on the chip base layer 210. The second chip pads 242 correspond to first back pads 14 to be described below. For example, top surfaces of the second chip pads 242 are coplanar with a top surface of the second chip protective layer 244. The second chip pads 242 are electrically connected to the first chip interconnection layer 220. In some embodiments, the second chip pads 242 are connected to the signal line patterns 230 of the first chip interconnection layer 220 through through-electrodes 250 that vertically penetrate the chip base layer 210. The second chip pads 242 include a conductive material such as a metal. For example, the second chip pads 242 include copper (Cu). The second chip protective layer 244 includes an insulating material. For example, the second chip protective layer 244 includes silicon oxide (SiO).

The semiconductor chip 200 is mounted on the substrate 100. As shown in FIG. 5, the front surface of the semiconductor chip 200 faces the substrate 100, and the semiconductor chip 200 is electrically connected to the substrate 100. The front surface of the semiconductor chip 200, such as a bottom surface of the first chip interconnection layer 220, is in direct contact with a top surface of the substrate 100. For example, the first chip protective layer 224 is in direct contact with the substrate protective layer 124 of the substrate 100. The first chip pads 222 of the semiconductor chip 200 are disposed to correspond to the first substrate pads 122 of the substrate 100, respectively. The first chip pads 222 of the semiconductor chip 200 are bonded to the first substrate pads 122 of the substrate 100.

A plurality of semiconductor chips 200 are provided. For example, another semiconductor chip 200 is mounted on the semiconductor chip 200. The front surface of the another semiconductor chip 200 faces the semiconductor chip 200. The front surface of the another semiconductor chip 200 is in direct contact with the back surface of the semiconductor chip 200. For example, the first chip interconnection layer 220 of the another semiconductor chip 200 is in direct contact with the second chip interconnection layer 240 of the semiconductor chip 200. For example, the semiconductor chips 200 are stacked such that the first chip protective layer 224 is in direct contact with the second chip protective layer 244.

The second chip pads 242 of the semiconductor chip 200 correspond to the first chip pads 222 of the another semiconductor chip 200. The first chip pads 222 and the second chip pads 242 of adjacent semiconductor chips 200 are bonded to each other. The semiconductor chips 200 are electrically connected to each other through the first chip pads 222 and the second chip pads 242. The plurality of semiconductor chips 200 and 200′ are stacked on the substrate 100, as described above.

Components of an uppermost semiconductor chip 200′ of the plurality of semiconductor chips 200 and 200′ of the chip stack CS partially differ from components of the other semiconductor chips 200. For example, the uppermost semiconductor chip 200′ does not have the second chip interconnection layer 240 and the through-electrodes 250.

A molding layer ML is disposed on the substrate 100. The molding layer ML covers the top surface of the substrate 100. The molding layer ML surrounds the chip stack CS. For example, the molding layer ML covers side surfaces of the semiconductor chips 200 and 200′. The molding layer ML protects the chip stack CS. The molding layer ML includes an insulating material. For example, the molding layer ML includes an epoxy molding compound (EMC). In some embodiments, unlike FIG. 5, the molding layer ML covers the chip stack CS. For example, the molding layer ML covers the back surface of the uppermost semiconductor chip 200′.

The semiconductor chips 200 and 200′ are mounted on the substrate 100 as shown in FIG. 5, but embodiments of the inventive concepts are not necessarily limited thereto. In some embodiments, the semiconductor chips 200 and 200′ are mounted on a base semiconductor chip. The base semiconductor chip is a wafer-level semiconductor substrate formed using a silicon wafer. The base semiconductor chip includes an integrated circuit. For example, the integrated circuit is one of a memory circuit, a logic circuit, or a combination thereof.

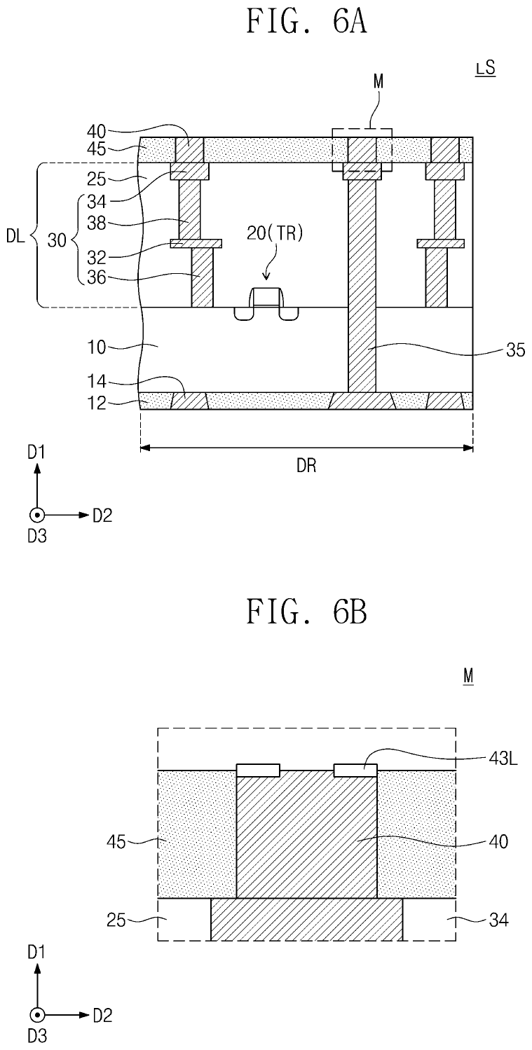

FIGS. 6A to 8 are cross-sectional views that illustrate a method of manufacturing a semiconductor package according to some embodiments of the inventive concepts.

Referring to FIG. 6A, in an embodiment, a wafer is provided. The wafer corresponds to a first semiconductor substrate 10 of FIG. 6A. A plurality of device regions DR are arranged in the first semiconductor substrate 10. Each of the device regions DR may be referred to as ‘a chip region’. In addition, a scribe lane region is disposed between adjacent device regions DR.

First semiconductor devices 20 are formed on a front surface of the first semiconductor substrate 10 by general processes. For example, a source and a drain are formed in an upper portion of the first semiconductor substrate 10 of each of the device regions DR, and a gate insulating layer and a gate electrode are formed on the first semiconductor substrate 10 between the source and the drain, thereby forming a transistor TR.

A first device interlayer insulating layer 25 and a first device interconnection portion 30 are formed on the first semiconductor substrate 10. For example, an insulating material is deposited on the front surface of the first semiconductor substrate 10 to form a lower portion of the first device interlayer insulating layer 25. First connection contacts 36 are formed that penetrate the lower portion of the first device interlayer insulating layer 25 and are connected to the first semiconductor substrate 10, and first signal line patterns 32 are formed on the lower portion of the first device interlayer insulating layer 25.

An insulating material is deposited on the lower portion of the first device interlayer insulating layer 25 to form an upper portion of the first device interlayer insulating layer 25. Second connection contacts 38 are formed that penetrate the upper portion of the first device interlayer insulating layer 25 and are connected to the first signal line patterns 32, and second signal line patterns 34 are formed on the upper portion of the first device interlayer insulating layer 25.

A first through-electrode 35 is formed that penetrates the upper portion and the lower portion of the first device interlayer insulating layer 25 and the first semiconductor substrate 10 in the first direction D1. An insulating material is deposited on the upper portion of the first device interlayer insulating layer 25 to complete the first device interlayer insulating layer 25.

A first protective layer 45 is formed on the first device interlayer insulating layer 25. First pads 40 are formed on the device regions DR, and the first protective layer 45 surrounds the first pads 40.

A first back protective layer 12 is formed on a back surface of the first semiconductor substrate 10. First back pads 14 are formed on back surfaces of the device regions DR, and the first back protective layer 12 surrounds the first back pads 14.

FIG. 6B is an enlarged cross-sectional view of a region ‘M’ of FIG. 6A. Referring to FIG. 6B, in an embodiment, a lower barrier pattern 43L is formed on a top surface of the first pad 40. The lower barrier pattern 43L is formed on both edges of the top surface of the first pad 40. The lower barrier pattern 43L is disposed along an edge of the top surface of the first pad 40 when viewed in a plan view. Like FIGS. 3 and 4A to 4C, a planar shape of the lower barrier pattern 43L is one of a circular shape, a cogwheel shape, a tetragonal shape, a triangular shape, or a polygonal shape. The lower barrier pattern 43L extends onto a top surface of the first protective layer 45 in the second direction D2.

A lower structure LS is formed as described above.

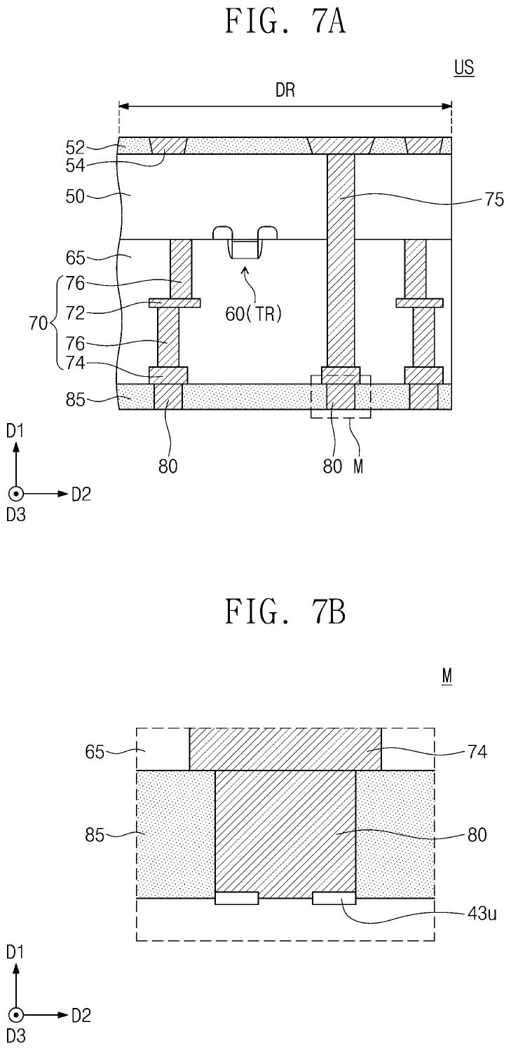

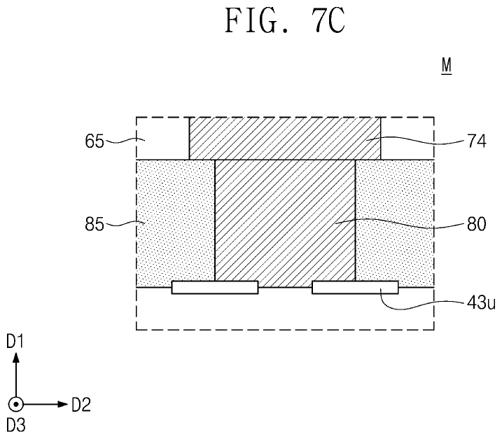

Referring to FIG. 7A, in an embodiment, an upper structure US is formed. A process of forming the upper structure US is substantially similar to a process of forming the lower structure LS. For example, second semiconductor devices 60 are formed on a second semiconductor substrate 50 that is provided as a wafer, a second device interlayer insulating layer 65, a second device interconnection portion 70 and a second through-electrode 75 are formed on the second semiconductor substrate 50, a second protective layer 85 and second pads 80 are formed on the second device interlayer insulating layer 65, and a second back protective layer 52 and second back pads 54 are formed on a back surface of the second semiconductor substrate 50.

FIG. 7B is an enlarged cross-sectional view of a region ‘M’ of FIG. 7A. Referring to FIG. 7B, in an embodiment, an upper barrier pattern 43U is formed on a bottom surface of the second pad 80. The upper barrier pattern 43U is formed on both edges of the bottom surface of the second pad 80. The upper barrier pattern 43U is disposed along an edge of the bottom surface of the second pad 80 when viewed in a plan view. Like FIGS. 3 and 4A to 4C, a planar shape of the upper barrier pattern 43U is one of a circular shape, a cogwheel shape, a tetragonal shape, a triangular shape, or a polygonal shape. Referring to FIG. 7C, in some embodiments, the upper barrier pattern 43U extends onto a bottom surface of the second protective layer 85 in the second direction D2.

An upper structure US is formed as described above.

The upper structure US is disposed on the lower structure LS. The front surface of the first semiconductor substrate 10 of the lower structure LS faces the front surface of the second semiconductor substrate 50 of the upper structure US. Thus, the first pads 40 of the lower structure LS are aligned with the second pads 80 of the upper structure US in the first direction D1. A top surface of the first protective layer 45 is in direct contact with a bottom surface of the second protective layer 85, and top surfaces of the first pads 40 are in direct contact with bottom surfaces of the second pads 80.

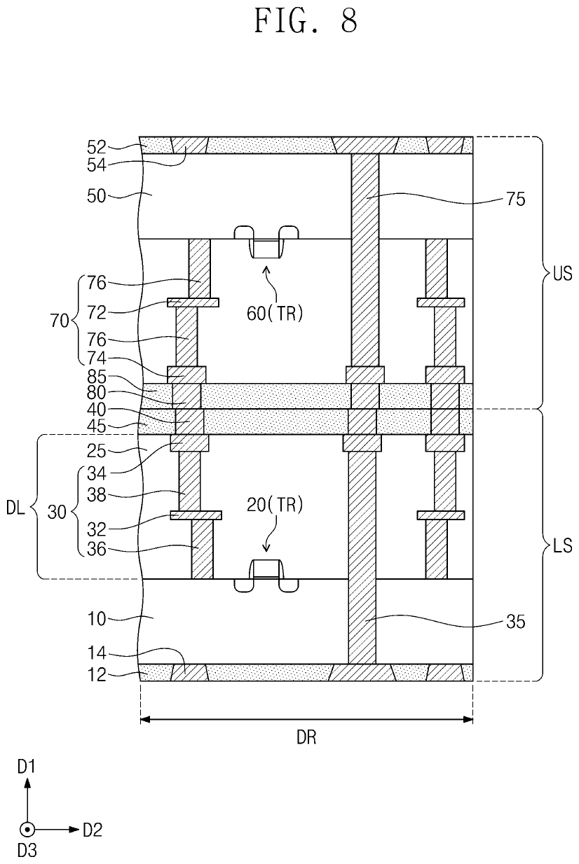

Referring to FIG. 8, in an embodiment, the lower structure LS and the upper structure US are bonded to each other. A thermal treatment process is performed on the lower structure LS and the upper structure US. The first pads 40 are bonded to the second pads 80 by the thermal treatment process. For example, the first pad 40 and the second pad 80 are bonded to each other to constitute a single integrated body.

The first pads 40 and the second pads 80 are formed of the same material, such as copper (Cu), etc., and the first pads 40 are bonded to the second pads 80 by a metal-metal hybrid bonding process performed using surface activation that is generated at an interface of the first pad 40 and the second pad 80, which are in contact with each other.

For example, the first pad 40 of FIG. 6B is bonded to the second pad 80 of FIG. 7B. When the first pad 40 is bonded to the second pad 80, the first and second pads 40 and 80 might not be completely aligned with each other. Thus, as shown in FIG. 1, the second pad 80 may be offset from the first pad 40 in the second direction D2. When the first pad 40 is bonded to the second pad 80, the lower barrier pattern 43L and the upper barrier pattern 43U overlap with each other to form first and second barrier patterns 43a and 43b. The lower barrier pattern 43L and the upper barrier pattern 43U may partially or completely overlap with each other.

A semiconductor package according to embodiments of the inventive concepts includes the pads bonded to each other, the protective layers that surround the pads, and the barrier pattern interposed between the pad and the protective layer. The barrier pattern is also disposed between the bonded pads to prevent copper ions of the pads from diffusing into the protective layers, which can prevent a short phenomenon of the semiconductor package. Thus, contact failure between the pads does not affect electrical characteristics of the semiconductor package. For example, failure occurrences can be reduced, structural stability of the semiconductor package is increased, and electrical connection of the semiconductor package is increased.

While embodiments of the inventive concepts have been particularly shown and described, it will be understood by one of ordinary skill in the art that variations in form and detail may be made therein without departing from the spirit and scope of the attached claims.

What is claimed is:

1. A semiconductor package, comprising:
a lower structure; and
an upper structure disposed on the lower structure,
wherein the lower structure comprises:
a first substrate;
a first through-electrode that penetrates the first substrate in a first direction;
a first pad connected to the first through-electrode; and
a first protective layer that surrounds the first pad,
wherein the upper structure comprises:
a second substrate; a second through-electrode that penetrates the second substrate in the first direction;
a second pad connected to the second through-electrode; and
a second protective layer that surrounds the second pad,
wherein the second pad is offset from the first pad in a second direction that crosses the first direction,
wherein the first pad includes a first portion that does not overlap the second pad, wherein the semiconductor package further comprises:
a first barrier pattern disposed between the first portion and the second protective layer,
wherein a portion of the first barrier pattern is disposed between the first pad and the second pad.

2. The semiconductor package of claim 1,
wherein the second pad includes a second portion that does not overlap the first pad,
wherein the semiconductor package further comprises:
a second barrier pattern disposed between the second portion and the first protective layer,
wherein a portion of the second barrier pattern is disposed between the first pad and the second pad.

3. The semiconductor package of claim 2, wherein the first and second barrier patterns are connected to each other and are disposed along an edge of the first pad, when viewed in a plan view.

4. The semiconductor package of claim 1, wherein the first barrier pattern includes at least one of Ti, Ta, or TiN.

5. The semiconductor package of claim 1, wherein a length of the first barrier pattern in the second direction ranges from 0.1 μm to 8 μm.

6. The semiconductor package of claim 1, wherein a thickness of the first barrier pattern in the first direction ranges from 1 Å to 100 Å.

7. The semiconductor package of claim 1, wherein the first barrier pattern is disposed between the first protective layer and the second protective layer.

8. The semiconductor package of claim 1, wherein a planar shape of the first pad is one of a circular shape, a tetragonal shape, a hexagonal shape, or a polygonal shape.

9. The semiconductor package of claim 1, wherein a planar shape of the first barrier pattern is one of a circular shape, a cogwheel shape, a triangular shape, a tetragonal shape, or a polygonal shape.

10. A semiconductor package, comprising:
a lower structure; and
an upper structure disposed on the lower structure,
wherein the lower structure comprises:
a first pad; and
a first protective layer that surrounds a side surface of the first pad,
wherein the upper structure comprises:
a second pad; and
a second protective layer that surrounds a side surface of the second pad,
wherein a top surface of the first pad is partially in contact with a bottom surface of the second pad,
wherein the first pad includes:
a first offset portion adjacent to the second protective layer; and
a first overlapping portion that overlaps the second pad,
wherein the second pad includes:
a second offset portion adjacent to the first protective layer; and
a second overlapping portion that overlaps the first pad,
wherein a first barrier pattern is disposed between the first offset portion and the second protective layer and between the first overlapping portion and the second pad, and
wherein a second barrier pattern is disposed between the second offset portion and the first protective layer and between the second overlapping portion and the first pad.

11. The semiconductor package of claim 10, wherein each of the first barrier pattern and the second barrier pattern includes at least one of Ti, Ta, or TiN.

12. The semiconductor package of claim 10, wherein a width of each of the first barrier pattern and the second barrier pattern ranges from 0.1 μm to 8 μm.

13. The semiconductor package of claim 10, wherein a thickness of each of the first barrier pattern and the second barrier pattern ranges from 1 Å to 100 Å.

14. The semiconductor package of claim 10, wherein a planar shape of each of the first pad and the second pad is one of a circular shape, a tetragonal shape, a hexagonal shape, or a polygonal shape.

15. The semiconductor package of claim 10, wherein the first and second barrier patterns are connected to each other and are disposed along an edge of the first pad, when viewed in a plan view.

16. The semiconductor package of claim 10, wherein a planar shape of each of the first barrier pattern and the second barrier pattern is one of a circular shape, a cogwheel shape, a triangular shape, a tetragonal shape, or a polygonal shape.

17. A semiconductor package, comprising:
a lower structure; and
an upper structure disposed on the lower structure,
wherein the lower structure comprises:
a first substrate that includes a first device region;
a first through-electrode that penetrates the first substrate in a first direction;
a first pad connected to the first through-electrode; and
a first protective layer that surrounds the first pad,
wherein the upper structure comprises:
a second substrate that includes the first device region;
a second through-electrode that penetrates the second substrate in the first direction;
a second pad connected to the second through-electrode; and
a second protective layer that surrounds the second pad,
wherein the second pad is offset from the first pad in a second direction that crosses the first direction and is in contact with the first pad,
wherein the semiconductor package further comprises a first barrier pattern disposed between the first pad and the second pad,
wherein the first barrier pattern includes:
a first barrier portion disposed on an edge of a top surface of the first pad;
a second barrier portion disposed on an edge of a bottom surface of the second pad, wherein the first barrier portion and the second barrier portion partially overlap each other,
a first single portion disposed between the first pad and the second protective layer; and
an overlap portion disposed between the first pad and the second pad and where the first barrier portion overlaps the second barrier portion, and
wherein a thickness of the first single portion is less than a thickness of the overlap portion.

18. The semiconductor package of claim 17, wherein the first barrier pattern further includes:
a second single portion that is a portion of the second barrier portion that does not overlap the first barrier portion,
wherein the second single portion is disposed between the first pad and the second pad, and
wherein a thickness of the second single portion is less than the thickness of the overlap portion.

19. The semiconductor package of claim 17, wherein the first barrier pattern includes at least one of Ti, Ta, or TiN.

20. The semiconductor package of claim 17, wherein a width in the second direction of the first barrier portion differs from a width in the second direction of the second barrier portion.
